(19) United States
(12) Patent Application Publication
(10) Pub. No.: US 2026/0304876 A1
(43) Pub. Date: Oct. 1, 2026

(54) STRAIN ENGINEERING OF MEMBRANE LAYERS IN HETEROSTRUCTURES

(71) Applicant: The University of Chicago, Chicago, IL (US)

(72) Inventors: Alexander A. High, Oakland, MD (US); Xinghan Guo, Chicago, IL (US); Zixi Li, Chicago, IL (US); Tianle Liu, Chicago, IL (US); Nazar Delegan, Chicago, IL (US); Joseph Paul Heremans, Chicago, IL (US)

(21) Appl. No.: 19/477,383

(22) PCT Filed: Apr. 25, 2024
(86) PCT No.: PCT/US2024/026157

§ 371 Date: Oct. 21, 2025

Related U.S. Application Data
(60) Provisional application No. 63/461,962, filed on Apr. 26, 2023.

(51) Int. Cl. H10D 62/83; G06N 10/40; H10D 62/81

(52) U.S. Cl. CPC H10D 62/8303; H10D 62/81; G06N 10/40

(57) ABSTRACT

Provided are methods of generating strain in membrane layers, including diamond membrane layers, in heterostructures. In embodiments, a method of forming a strained membrane layer comprises heating a heterostructure, the heterostructure comprising a membrane layer, a substrate, and a bonding layer between the membrane layer and the substrate, under conditions to cure the bonding layer and form a bonded heterostructure, wherein the membrane layer and the substrate have a thermal expansion ratio mismatch; and cooling the bonded heterostructure under conditions to convert the membrane layer in the bonded heterostructure to a strained membrane layer characterized by a strain profde comprising anon-zero strain value, wherein the strained membrane layer comprises a suspended region and a supported region and wherein the suspended region exhibits a strain value greater than a strain value exhibited by the supported region. Bonded heterostructures comprising the strained membrane layers are also provided.

### CROSS-REFERENCE TO RELATED APPLICATIONS

The present application claims priority to U.S. provisional patent application No. 63/461,962 that was filed Apr. 26, 2023, the entire contents of which are incorporated herein by reference.

### REFERENCE TO GOVERNMENT RIGHTS

This work is primarily supported by Q-NEXT, a U.S. Department of Energy Office of Science National Quantum Information Science Research Center.

### BACKGROUND

Group-IV color centers in diamond, including the negatively-charged and neutral silicon vacancy (SiV⁻, SiV⁰), germanium vacancy (GeV⁻) and tin vacancy (SnV⁻) are a leading material platform in quantum networking. Generally, coherent operation of SiV⁻ and GeV⁻ color centers requires costly, resource-intensive dilution refrigerators and vector magnets or, in the case of SnV⁻ color centers, low-fidelity all-optical control schemes. Techniques have been developed for inducing strain in the diamond so as to tune critical quantum state properties of the group-IV color centers. However, existing techniques are limited in the magnitude and control over the strain induced and can also damage the diamond, impairing the quantum state properties of the group-IV color centers therein.

### SUMMARY

Provided are methods of generating strain in membrane layers, including diamond membrane layers, in heterostructures. Bonded heterostructures comprising the strained membrane layers are also provided.

In one aspect, a method of forming a strained membrane layer is provided which comprises heating a heterostructure, the heterostructure comprising a membrane layer, a substrate, and a bonding layer between the membrane layer and the substrate, under conditions to cure the bonding layer and form a bonded heterostructure, wherein the membrane layer and the substrate have a thermal expansion ratio mismatch; and cooling the bonded heterostructure under conditions to convert the membrane layer in the bonded heterostructure to a strained membrane layer characterized by a strain profile comprising a non-zero strain value, wherein the strained membrane layer comprises a suspended region and a supported region and wherein the suspended region exhibits a strain value greater than a strain value exhibited by the supported region.

In another aspect, a bonded heterostructure is provided which comprises a strained membrane layer characterized by a strain profile comprising a non-zero strain value; a substrate; and a cured bonding layer between the strained membrane layer and the substrate, wherein the strained membrane layer is composed of a material having a thermal expansion ratio mismatch with the substrate, and the strained membrane layer comprises a suspended region and a supported region, wherein the suspended region exhibits a strain value greater than a strain value exhibited by the supported region

Other principal features and advantages of the disclosure will become apparent to those skilled in the art upon review of the following drawings, the detailed description, and the appended claims.

### BRIEF DESCRIPTION OF THE DRAWINGS

Illustrative embodiments of the disclosure will hereafter be described with reference to the accompanying drawings.

FIGS. 1A and 1B show cross-sectional schematic images of heterostructures according to illustrative embodiments.

FIG. 2A shows a perspective view of a bonded heterostructure according to an illustrative embodiment. FIG. 2B shows a top-down view of a zoomed in portion of the bonded heterostructure of FIG. 2A.

FIG. 3A shows a plot of the strain profile of the strained membrane layer of the bonded heterostructure of FIG. 2A as measured along the x axis. FIG. 3B shows a plot of the strain profile of the strained membrane layer of the bonded heterostructure of FIG. 2A as measured along the y axis. FIG. 3C is a copy of the image shown in FIG. 2B. FIG. 3D is a plot of orbital splitting energy of color centers in the strained membrane layer as measured at various locations in certain regions of the strained membrane layer (the regions are labeled with dots in FIG. 3C).

FIG. 4A shows a top-down view of a bonded heterostructure according to an illustrative embodiment. FIG. 4B shows a plot of the strain profile of the strained membrane layer as measured along the polar direction. FIG. 4C shows a plot of the strain profile of the strained membrane layer as measured along the normal direction.

FIG. 5A shows a perspective view of a bonded heterostructure according to an illustrative embodiment. FIG. 5B shows a plot of the strain profile of the strained membrane layer of the bonded heterostructure of FIG. 5A as measured along the x axis. FIG. 5C shows a plot of the strain profile of the strained membrane layer of the bonded heterostructure of FIG. 5A as measured along the y axis.

FIG. 6 shows a cross-sectional schematic of a bonded heterostructure according to an illustrative embodiment that further includes a pair of gold electrodes to achieve active strain tuning.

FIG. 7 shows photoluminescence spectra from GeV⁻ color centers in an unstrained diamond membrane layer and in a strained diamond membrane layer according to an illustrative embodiment. The strain profiles disclosed herein include strain values sufficient to increase orbital splitting of GeV⁻ color centers to an extent that enables coherence at 4 K and microwave control without the need for vector magnets.

FIG. 8A is a plot of strain in a strained diamond membrane layer of an illustrative bonded heterostructure versus width of a central portion of a suspended region (beam) of the strained diamond membrane layer, at various lengths of the central portion. FIG. 8B is a plot of orbital splitting of GeV⁻ color centers within the strained diamond membrane layer versus width and at various lengths. FIG. 8C shows a top-down view of a zoomed in portion of the bonded heterostructure showing the beam and its central portion (labeled with the dotted rectangle). FIG. 8D shows a photoluminescence spectrum from GeV⁻ color centers in the central portion of the strained diamond membrane layer.

### DETAILED DESCRIPTION

In embodiments, a method of forming a strained membrane layer comprises heating a heterostructure, the heterostructure comprising a membrane layer, a substrate, and a bonding layer between the membrane layer. The heating is carried out under conditions to cure the bonding layer and form a bonded heterostructure. The bonding layer in the bonded heterostructure may be referred to as a cured bonding layer. The method further comprises cooling the bonded heterostructure. The cooling is carried out under conditions to convert the membrane layer in the bonded heterostructure to a strained membrane layer. The membrane layer in the cooled, bonded heterostructure may be referred to as a strained membrane layer. The meaning of “strained” is further described below, including by reference to illustrative strain values. As further described below, parameters such as membrane layer patterning, substrate patterning, material selection of the membrane layer and the substrate, and combinations thereof, may be selected to achieve a desired strain profile for the strained membrane layer in the bonded heterostructure. This includes strained membrane layers comprising region(s) exhibiting unexpectedly high strain values (e.g., 0.7%). Surprisingly, the integrity of the bonded heterostructure is retained despite such high strain, e.g., the strained membrane layer is capable of withstanding the high strain without damage or debonding from the underlying bonding layer.

In the present disclosure, the term “strain” (and similar terms, e.g., “strained”) refers to the spatial dislocation of atoms of the membrane layer induced by the external stress imposed by the cured bonding layer as compared to the atoms of the membrane layer in absence of the external stress (i.e., in the unstrained membrane layer). As such, this strain may be represented as a 3×3 tensor. The phrase “strain value” refers to the total strain at a particular location within the strained membrane layer and is given by the norm of the 3×3 tensor. However, the value and the susceptibility of the off-diagonal elements (ε_{xy}, ε_{xz}, ε_{yx}, ε_{yz}, ε_{zx}, ε_{zy}) in the 3×3 tensor are generally sufficiently small as compared to the diagonal elements (εₓₓ, ε_{yy}, ε_{zz}), such that the off-diagonal elements may be considered to be zero.

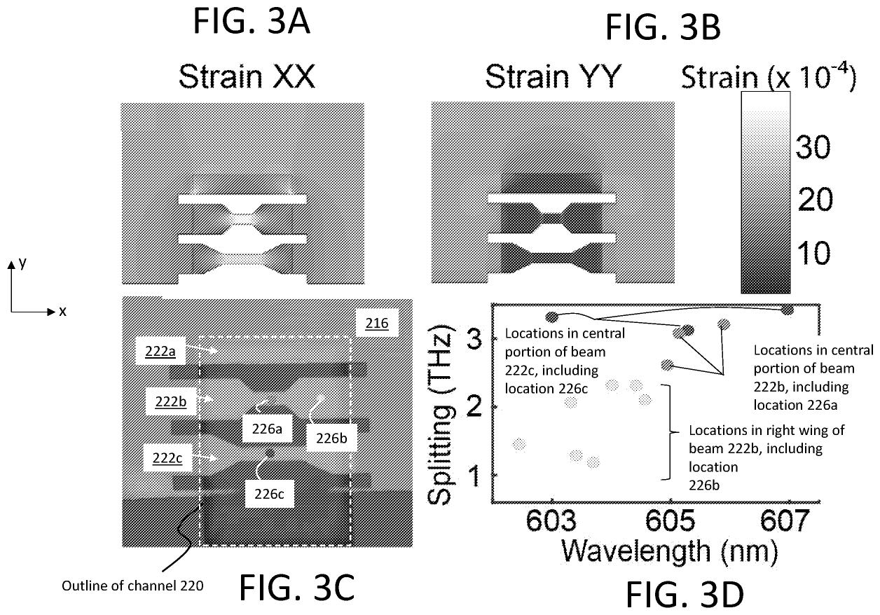

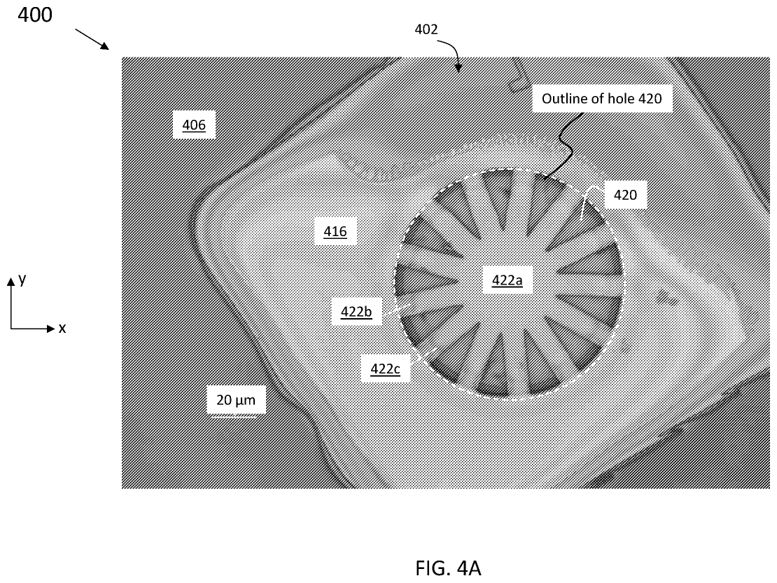

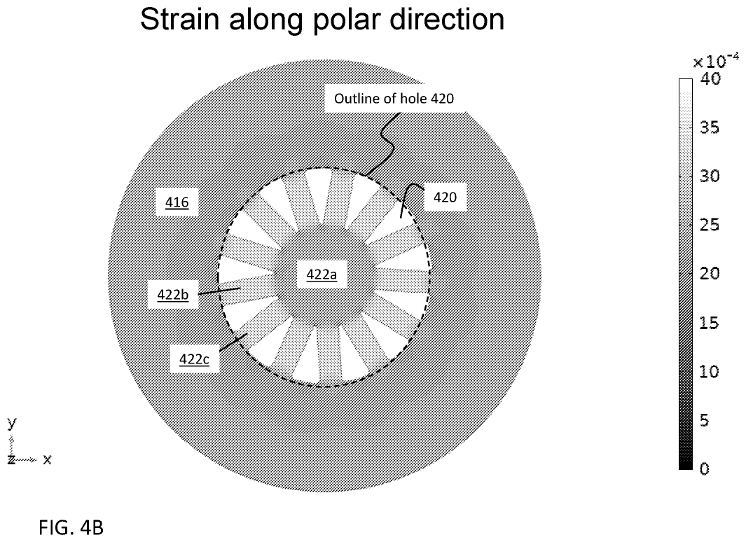

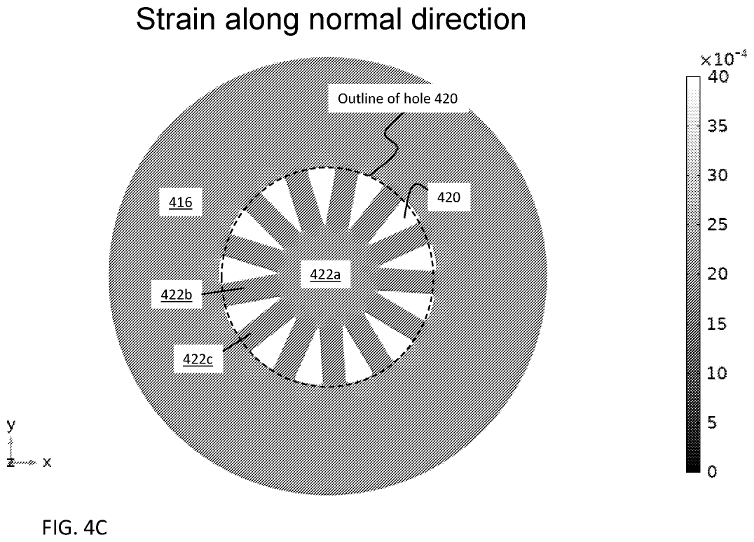

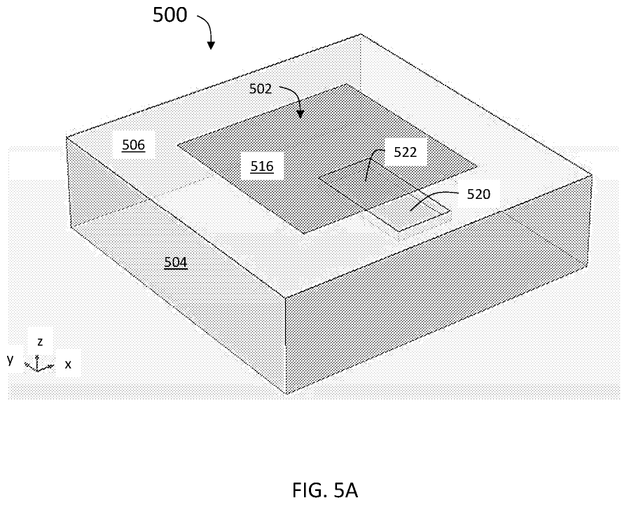

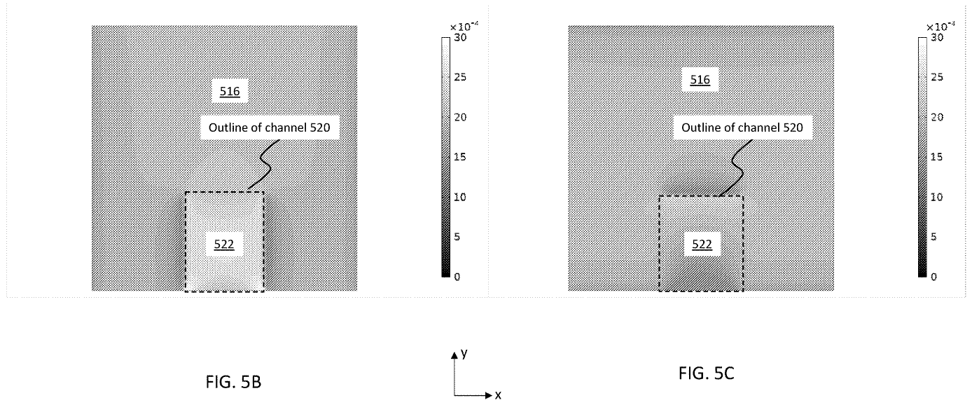

Thus, the strain value at a particular location within the strained membrane layer may be given as \sqrt{(εₓₓ²+ε_{yy}²+ε_{zz}²)}. The phrase “average strain value” refers to an average of the strain values at a representative number (e.g., 10, 20, 30, etc.) of locations within the strained membrane layer. The phrase “strain type” refers to the nature of the spatial dislocation as being compressive (the atoms forced closer together) or tensile (the atoms forced further apart). The phrase “strain profile” (and similar terms, e.g., “strain distribution”) refers to both the strain value as well as the strain type in the strained membrane layer as a function of position within the strained membrane layer. The strain profile may refer to the strain (i.e., value, type) as measured along a particular direction within the strained membrane layer. For example, assuming the plane defined by the strained membrane layer is the xy plane, the strain profile may refer to the strain as measured along the x axis (see FIGS. 3A and 5B) or the strain profile may refer to the strain as measured along the y axis (see FIGS. 3B and 5C). As another example, the strain profile may refer to the strain as measured along the polar direction (see FIG. 4B) or as measured along the direction normal to the polar direction (see FIG. 4C). These strain profiles and strain values along these strain profiles are further described below.

The strain profiles of the strained membrane layers may be measured using the theoretical simulations as described in the Example, below. Experimental techniques may also be used to measure the strain profiles. For example, X-ray diffraction imaging may be used to measure strain profiles. Specifically, by raster scanning a coherent X-ray beam and acquiring a diffraction pattern for each sample position (referred to as Bragg ptychography), the nanoscale variation in crystal structure can be imaged so as to extract the strain profile. (See Hruszkewycz, S. O., et al. APL Materials 5.2 (2017): 026105, which is hereby incorporated by reference in its entirety.)

The present disclosure is based, at least in part, on findings that the present methods can achieve strained membrane layers comprising region(s) exhibiting unexpectedly high strain values. This includes findings that patterning of the membrane layer, the bonding layer, the substrate, and combinations thereof, may be leveraged to the high strain values. The term “patterning” refers to altering the morphology of the membrane layer (bonding layer/substrate) or a surface thereof, from that of an initial morphology. Patterning may involve removing material from specific regions of the membrane layer (bonding layer/substrate), including removing material from regions defined entirely within a perimeter thereof (which may be that of a rectangle or square). Patterning may include removing material from regions at the perimeter of the membrane layer (bonding layer/substrate) so as to alter the shape and dimensions of the perimeter. However, at least in embodiments, patterning requires removing material from at least some regions defined entirely within the perimeter of the membrane layer (bonding layer/substrate). That is, at least in embodiments, simply altering the shape and dimensions of the perimeter of the membrane layer (bonding layer/substrate) by removing material therefrom does not constitute patterning as that term is defined herein. A patterned membrane layer (patterned bonding layer/patterned substrate) refers to the membrane layer (bonding layer/substrate) having an altered morphology due to such patterning. As further described below, the present methods may include the step of patterning the membrane layer, patterning the bonding layer, patterning the substrate, and combinations thereof, so as to achieve any of the strained membrane layers having any of the strain profiles disclosed herein.

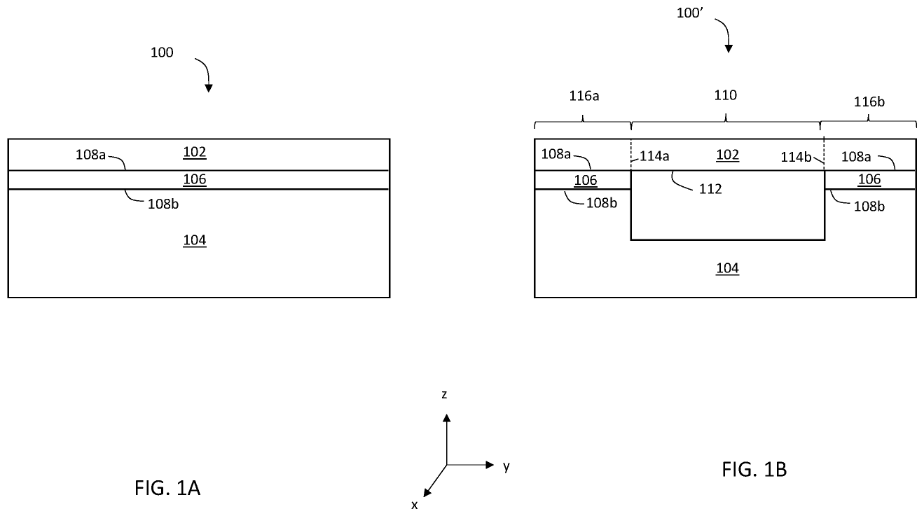

In embodiments (which may be achieved by such patterning), the membrane layer may comprise one or more suspended regions and one or more supported regions. A “suspended region” refers to that portion of the membrane layer that is not in contact with, and is thus unsupported by, the bonding layer. By contrast, a “supported region” refers to that portion of the membrane layer that is in contact with, and is thus supported by, the bonding layer. Such regions are illustrated with reference to FIGS. 1A and 1B. These figures show a cross-sectional image of a heterostructure 100 (which may be a bonded heterostructure) comprising a membrane layer 102, a substrate 104, and a bonding layer 106 therebetween. The bonding layer 106 is in direct contact with the membrane layer 102 forming an upper interface 108a between a bottom surface of the membrane layer 102 and a top surface of the bonding layer 106. The bonding layer 106 is also in direct contact with the substrate 104 forming a lower interface 108b between a bottom, opposing surface of the bonding layer 106 and a top surface of the substrate 104. The configuration of FIG. 1A provides the membrane layer 102 as a supported membrane layer 102 consisting of a single supported region, since the entire bottom surface of the membrane layer 102 is supported by and in contact with the bonding layer 106.

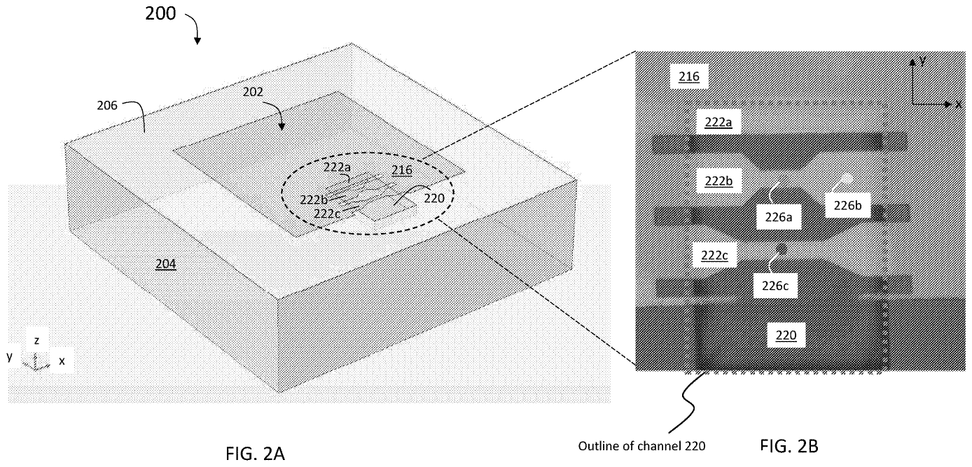

By contrast, in the heterostructure 100′ shown in FIG. 1B, portions of the bonding layer 106 and the substrate 104 have been removed (i.e., patterned). This results in the membrane layer 102 comprising a suspended region 110 defined as that portion of the membrane layer 102 which is not in contact with the bonding layer 106 at the bottom surface 112 of the membrane layer 102. The suspended region 110 is anchored at a first end 114a to a first supported region 116a and anchored at a second, opposing end 114b to a second supported region 116 b. Each supported region 116a, b is defined as that portion of the membrane layer 102 which is in contact with the bonding layer 106 at its bottom surface 112, thereby forming the interface 108a. Together, the suspended region 110 and the supported regions 116a, b (and any other suspended and supported regions that may be present) constitute the membrane layer 102. It is noted that the designation of “first” and “second” supported region 116a, b does not necessarily imply that these are individual, distinct regions from one another as, together, they may constitute a single supported region anchored to both ends 114a, 114b of the suspended region. This is illustrated in FIG. 2A, which is further described below.

The particular shape and dimensions of the suspended region(s), supported region(s), and arrangement of such regions with respect to one another in the membrane layer may be selected to achieve a strained membrane layer having a particular strain profile. The arrangement of such regions also encompasses the relative positioning of the membrane layer and the underlying bonding layer/substrate. As further described below with respect to FIGS. 3A-3C, such positioning includes selecting a particular orientation of a crystallographic axis(es) of the membrane layer relative to a feature(s) (e.g., a cavity) defined in an underlying patterned substrate. The shape and dimensions of the feature(s) defined in such patterned substrates also affect the strain profile of the strained membrane layer and thus, may be selected to achieve a particular strain profile.

The particular strain profile selected for the strained membrane layer may include providing the strained membrane layer with a region(s) exhibiting a particular strain value or strain type. For example, a maximum strain value in the strained membrane layer may be located within a suspended region(s) of the strained membrane layer. As another example, one or more (including all) suspended regions of the strained membrane layer may exhibit greater strain values or greater average strain values as compared to the strain values/average strain values of one or more (including all) supported regions of the strained membrane layer. In other embodiments, each suspended region of the strained membrane layer may exhibit greater strain values or a greater average strain value as compared to strain values/average strain value of each supported region of the strained membrane layer. However, these examples/embodiments are not intended to be limiting as the present methods also achieve suspended region(s) which exhibit smaller strain values or smaller average strain values as compared to supported region(s) of the strained membrane layer. Illustrative strained membrane layers and their corresponding strain profiles are shown in FIGS. 2A-5C.

Regarding FIG. 2A, this figure shows a perspective view of a bonded heterostructure 200 comprising a strained membrane layer 202 (in this embodiment, a strained diamond membrane layer), a substrate 204 (in this embodiment, a fused silica substrate), and a cured bonding layer 206 (in this embodiment, cured hydrogen silsesquioxane). The substrate 204 is patterned to define a rectangularly shaped cavity 220 extending into the substrate 204 from the upper surface of the substrate 204. The cavity 220 is surrounded on all sides (and its bottom) by the material of the substrate 204 since it is positioned within the perimeter of the substrate 204 and extends only partially downwardly into the substrate 204. The strained membrane layer 202 is patterned (and positioned relative to the cavity 220) to define three separated and suspended regions 222a, 222b, and 222c. As shown in FIG. 2B (which corresponds to a zoomed in portion of the dotted circle of FIGS. 2A), the suspended region 222a has a rectangular shape with one long side and opposing short sides anchored to a supported region 216 of the strained membrane layer 202. The opposing long side of the suspended region 222a is exposed, as the patterning defines a gap between suspended regions 222a and 222b. The supported region 216 is that portion of the strained membrane layer 202 that overlies and is in contact with the underlying cured bonding layer 206. The suspended regions 222b, 222c each are in the form of a bow-tie shaped beam comprising a narrow, central portion and side wings (although the exact shape and dimensions of each bow-tie shaped beam differ). The opposing long sides of each suspended region 222b, c are exposed while the opposing short sides of each suspended region 222b, c are anchored to the supported region 216 of the membrane layer 202. Locations 226a, 226b within central portion and right wing of the suspended region 222b, respectively, are labeled. Location 226c within the central portion of the suspended region 222c is labeled.

FIG. 3A shows the strain profile of the strained membrane layer 202 of FIGS. 2A-2B as measured along the x axis. FIG. 3B shows the strain profile of the strained membrane layer 202 measured along the y axis. The image of FIG. 2B is repeated in FIG. 3C to facilitate comparison of locations 226 a-c within suspended regions 222b, c and the strain values at these locations within these regions. This comparison shows that strain values (along x) in the central portion of the suspended region 222b (including location 226a) are generally greater than strain values (along x) in the central portion of the suspended region 222c (including location 226c), which in turn are generally greater than strain values (along x) in the right wing of the suspended region 222b (including location 226b). The central portion of the suspended region 222b (encompassing location 226a) exhibits the maximum strain value (about 0.4%) in the strained membrane layer 202. FIG. 3A also shows that the strain values at the bottom corners of the suspended region 222a are greater than those within the rest of the suspended region 222a. Finally, FIG. 3A also shows that the average strain value (along x) in each suspended region 222a-c is greater than the average strain value (along x) in the supported region 216.

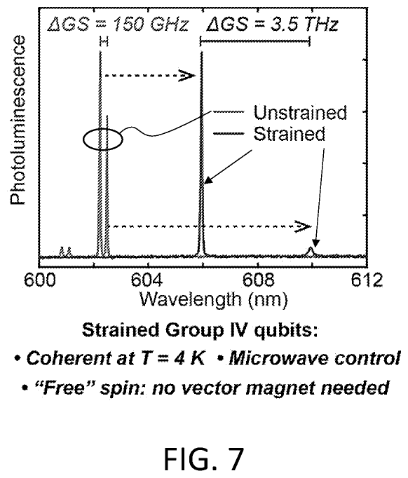

Together, FIGS. 3A-3B also illustrate how the particular shape and dimensions of the suspended region(s), supported region(s), and arrangement of such regions with respect to one another in the membrane layer achieve a particular strain profile for the strained membrane layer. Finally, as shown in FIG. 3D, this particular strain profile includes strain values sufficient to increase orbital splitting of color centers positioned within regions marked by locations 226a-c. This is further illustrated in FIG. 7, which shows photoluminescence spectra from GeV⁻ color centers in an unstrained diamond membrane layer and in a strained diamond membrane layer. The strain profiles disclosed herein include strain values sufficient to increase orbital splitting of GeV⁻ color centers so as to enable coherence at 4 K and microwave control without the need for vector magnets.

Moreover, the strain profiles of FIGS. 3A-3B further show that suspended regions 222 a-c (particularly suspended regions 222b, c) include locations exhibiting very high strain values along the x axis (i.e., large εₓₓ) but almost zero strain values along the y axis (i.e., ε_{yy}~0). This demonstrates the unique and powerful ability of the present methods to control the strain anisotropy within the strained membrane layer, which may be leveraged to achieve precise tuning of the electronic structure of chemical species (e.g., color centers) within the strained membrane layer.

For example, the strained diamond membrane layer 202 may be turned about 45° relative to its position shown in FIG. 3C so that the <110> crystallographic axis of the diamond runs parallel to the length of the cavity 220. In such a configuration, color centers positioned within regions marked by locations 226a, c will be grouped in two subsets. Specifically, diamond is a solid-state crystal having a diamond cubic lattice type. The lattice of a crystal generally affects the behavior of species therein. In the diamond cubic lattice type, all covalent bonds (sp³ bonds between carbons) are along <111> directions. However, the surface of the strained diamond membrane layer 202 may be a [100] surface with all edges being <100> edges. In such a case, the covalent bonds are projected in the <110> direction in the [100] surface. Group IV color centers in diamond may be formed by removing two adjacent carbon atoms and inserting one group IV atom in between. Therefore, the axis along the covalent bond between the two carbon atoms (which is along the <111> direction) becomes the main symmetry axis of the color center. Thus, the electron spin of the color center is quantized along this direction, i.e., the “quantization axis”. The plane that is normal, or perpendicular to the quantization axis, is the equator plane. In global coordinates (which is the laboratory frame), all x, y and z are along <100> directions. In local coordinates, however, the quantization axis (main axis) is the z? direction, and both x′ and y′ are in the equator plane, normally <110> and <112>. The strain in the strained diamond membrane layer 202 affects the behavior of the color centers therein in different ways, depending on the form of the strain tensor in these local coordinates. Strain along the quantization axis (<111>) will mostly shift the optical emission wavelength of the color center. However, the strain in the equator plane will split the ground state branches of the electron spin qubit, which can have multiple interesting implications, such as protected coherence of the spin qubit at elevated temperatures, and microwave control of the spin qubit. Therefore, by placing the strained diamond membrane layer 202 about 45° as noted above, the qubits form two different subsets. For one subset, the strain in global x will translate to about half along the quantization axis and half in equator plane. For the other subset, the strain in global x will totally translate to the equator plane. Therefore, the two subsets will have very different behaviors, a result achievable by using the present methods.

Regarding FIG. 4A, this figure shows a top-down view of a bonded heterostructure 400 comprising a strained membrane layer 402 (in this embodiment, a strained diamond membrane layer), a substrate (not labeled, but in this embodiment, a fused silica substrate), and a cured bonding layer 406 (in this embodiment, cured hydrogen silsesquioxane). The substrate is patterned to define a round cavity 420 (the outline of which is labeled) extending into the substrate from the upper surface of the substrate. The cavity 420 is surrounded on all sides (and its bottom) by the material of the substrate since it is positioned within the perimeter of the substrate and extends only partially downwardly into the substrate. The strained membrane layer 402 is patterned (and positioned relative to the cavity 420) to define a central hub and thirteen rectangularly shaped spokes (beams) extending radially from the central hub. The central hub forms a first suspended region 422a of the strained membrane layer 402 while the thirteen spokes form thirteen additional suspended regions, two of which are labeled 422b and 422c. The central hub (first suspended region 422a) is anchored only to respective short sides of each spoke (thirteen additional suspended regions, including 422b, c), while opposing short sides of each spoke are anchored to a supported region 416 of the strained membrane layer 202. Opposing long sides of the spokes are exposed due to the gaps defined by patterning. The supported region 416 is that portion of the strained membrane layer 402 that overlies and is in contact with the underlying cured bonding layer 406.

FIG. 4B shows the strain profile of the strained membrane layer 402 of FIG. 4A as measured in the polar direction, i.e., along each spoke. Each spoke (thirteen additional suspended regions, including 422b, c) exhibits the maximum strain value (about 0.28%) in the strained membrane layer 402, about the same average strain value to one another, and an average strain value greater than the average strain value of the supported region 416. By contrast, the central hub (first suspended region 422a) exhibits a smaller average strain value as compared to that of each spoke and about the same average strain value as the supported region 416. FIG. 4C shows the strain profile of the strained membrane layer 402 as measured in the direction normal to the polar direction.

Together, FIGS. 4A-4B further illustrate how the particular shape and dimensions of the suspended region(s), supported region(s), and arrangement of such regions with respect to one another in the membrane layer achieve a particular strain profile for the strained membrane layer.

Regarding 5A, this figure shows a perspective view of a bonded heterostructure 500 comprising a strained membrane layer 502 (in this embodiment, a strained silicon membrane layer), a substrate 504 (in this embodiment, a fused silica substrate), and a cured bonding layer 406 (in this embodiment, cured hydrogen silsesquioxane). The substrate 504 is patterned to define a rectangularly shaped cavity 520 extending into the substrate 504 from the upper surface of the substrate 504. The cavity 520 is surrounded on all sides (and its bottom) by the material of the substrate 504 since it is positioned within the perimeter of the substrate 504 and extends only partially downwardly into the substrate 504. The strained membrane layer 502 is unpatterned, but positioned relative to the cavity 520) to define a rectangularly shaped suspended region 522 having one short side and opposing long sides anchored to a supported region 516 of the strained membrane layer 502. The supported region 516 is that portion of the strained membrane layer 502 that overlies and is in contact with the underlying cured bonding layer 506.

FIG. 5B shows the strain profile of the strained membrane layer 502 of FIG. 5A as measured along the x axis. FIG. 5C shows the strain profile of the strained membrane layer 502 measured along the y axis. The outline of the cavity 520 is labeled. The suspended region 522 exhibits the maximum strain value (about 0.3%) in the strained membrane layer 502. FIGS. 5B-5C also show that the average strain value (along both x and y) in the suspended region 522 is greater than the average strain value (along both x and y) in the supported region 516.

Together, FIGS. 5A-5C further illustrate how the particular shape and dimensions of the suspended region(s), supported region(s), and arrangement of such regions with respect to one another in the membrane layer achieve a particular strain profile for the strained membrane layer.

Other shapes, dimensions, and arrangements of suspended regions and supported regions may be used as compared to the specific configurations illustrated in FIGS. 2A-5C. However, the term “beam” may be used to refer to a suspended region having at least two (generally opposing) anchored sides and remaining sides (e.g., two, generally opposing) which are exposed. In another embodiment, a suspended region may be in the form of a cantilever which refers to structures having a single anchored side and remaining sides (e.g., three, generally two opposing and one perpendicular thereto) which are exposed. In each of the embodiments, the specific shape of the exposed sides may vary. Similarly, other shapes and dimensions may be used for cavities defined within the substrate as compared to the specific configurations illustrated in FIGS. 2A-5C. However, the term “embedded” may be used to refer to cavities which extend from an upper surface of the substrate and only partially downwardly into the substrate and which are positioned entirely within the perimeter of the substrate such that all sides are surrounded by the material of the substrate.

As noted above, the strain profiles of the present strained membrane layers further depend upon the selection of the materials of the heterostructure, including that of the membrane layer and the substrate. Thus, material selection may be guided by a desired strain profile for the strained membrane layer. However, the materials are selected such that the membrane layer and the substrate have different thermal expansion ratios, i.e., a thermal expansion ratio mismatch. This ensures that strain develops in the membrane layer as the bonded heterostructure is cooled during the present methods. The degree of thermal expansion ratio mismatch is proportional to the strain values exhibited by the strained membrane layer such that a greater mismatch generates greater strain values. In embodiments, the thermal expansion ratio mismatch is at least 0.05×10⁻⁶ K⁻¹. This includes at least 0.1×10⁻⁶ K⁻¹, at least 0.3×10⁻⁶ K⁻¹, at least 0.5×10⁻⁶ K⁻¹, at least 1×10⁻⁶ K⁻¹, at least 5×10⁻⁶ K⁻¹, at least 10×10⁻⁶ K⁻¹, or in a range of from 0.5×10⁻⁶ K⁻¹ to 25×10⁻⁶ K⁻¹. These thermal expansion ratio mismatches may be average values referenced with respect to a temperature range, e.g., from 50 K to 750 K, from 75 K to 750 K, or from 100 K to 750 K. The strain type is determined by which of the membrane layer and the substrate has the larger thermal expansion ratio. In embodiments, the membrane layer has a thermal expansion ratio that is greater than that of the substrate (wherein the specific thermal expansion ratio mismatch may include any of those disclosed above). This results in tensile strain. In embodiments, the membrane layer has a thermal expansion ratio that is smaller than that of the substrate (wherein the specific thermal expansion ratio mismatch may include any of those disclosed above). This results in compressive strain.

Outside of the guidance provided above, material selection for the membrane layer and the substrate is otherwise not particularly limited. In embodiments, the membrane layer comprises (or consists of) diamond. Such a membrane layer may be referred to as a diamond membrane layer. The diamond in such a membrane layer comprises (or consists of) a solid carbon matrix in which the carbon atoms are substantially sp³ hybridized. The diamond may be characterized by its degree of crystallinity, which is generally high. In embodiments, the diamond is single-crystalline, i.e., to provide a single-crystal diamond membrane layer. The diamond membrane layer may be characterized by its lattice structure at the surface of the diamond membrane layer opposite that of the surface forming the interface with the bonding layer. In embodiments, this surface is [100] diamond.

Other illustrative materials that may be used to provide the membrane layer include silicon and silicon-containing compounds, e.g., silicon carbide, silicon germanium; group II-V semiconductor compounds, e.g., InAs, BN; and transition metal dichalcogenides. The membrane layer may comprise (or consist of) any of these materials or combinations thereof.

In addition to the illustrative materials for the membrane layer described above, the membrane layer generally further comprises a chemical species having an electronic structure that changes as a function of strain in the membrane layer. The chemical species may be provided by the material(s) of the membrane layer itself or be added (e.g., by doping) to any of the material(s) described above. In embodiments the chemical species comprise a color center. Illustrative color centers include group-IV color centers, e.g., silicon vacancies (SiV⁻, SiV⁰), germanium vacancies (GeV⁻), nitrogen vacancies (NV⁻), tin vacancies (SnV⁻), and combinations thereof. Other illustrative chemical species include quantum dots, qubits, and quantum wells. A single type or multiple different types of chemical species may be included.

The membrane layer (e.g., diamond membrane layer) is characterized by having a thickness that is substantially less than that of the other two dimensions of the membrane layer. The thickness refers to the dimension of the membrane layer along the z axis, while the two other dimensions refer to the dimensions of the membrane layer along the xy plane. (See FIGS. 1A-1B.) The thickness is generally nanoscale, i.e., no more than 1 μm. This includes having a thickness of no more than 750 nm, no more than 500 nm, no more than 250 nm, or in a range of from 3 nm to 250 nm, from 100 nm to 200 nm, or from 5 nm to 50 nm. Extremely thin membrane layers may be used, including those having a thickness in a range of from 10 nm to 15 nm. The thickness of the membrane layer may be measured from atomic force microscopy (AFM) images and a profilometer. The thickness values may refer to an average value as determined from such AFM images/profilometry. The other two dimensions of the membrane layer are not particularly limited, although they are greater than its thickness, e.g., in a range of from 10 μm to 10 mm. Thus, the membrane layers may be characterized as having a planar, two-dimensional morphology. The shape of the perimeter of the membrane layer as defined by the two dimensions perpendicular to the thickness is not particularly limited. As described above, patterning may be used to alter this perimeter as well as to remove portions of the membrane layer within its perimeter so as to define any of the suspended regions and supported regions described above.

The membrane layer (e.g., diamond membrane layer) may be further characterized by having low surface roughness. Surface roughness may be quantified by reference to root-mean-square roughness values (Rq) as determined, e.g., by using atomic force microscopy (AFM). In embodiments, the membrane layer has an Rq value in a range of from 0.2 nm to 0.9 nm as measured over an AFM area of from 0.04 to 100 μm²). This includes from 0.2 nm to 0.6 nm and from 0.2 nm to 0.4 nm.

The membrane layer is distinguished from the bulk form of the material from which the membrane layer is composed. For example, a diamond membrane layer is distinguished from bulk diamond which refers to diamond having substantially greater thicknesses than those described above, including thicknesses of greater than about 50 μm.

Techniques for synthesizing diamond membrane layers include those described in described in X. Guo, et al., Nano Letters 21, 10392 (2021), which is hereby incorporated by reference in its entirety. Briefly, such a method involves carrying out He⁺ implantation and annealing on a single-crystal, optical grade diamond mother substrate, diamond overgrowth via plasma enhanced chemical vapor deposition (PE-CVD), color center incorporation via either ion implantation post-isotopically (¹²C) purified overgrowth or in situ doping, and diamond membrane undercutting via electrochemical etching (EC). Other methods may be used to synthesize diamond membrane layers. Various thin film growth and deposition techniques may be used to synthesize membrane layers having other compositions.

As noted above, the substrate is composed of material(s) such that the substrate has a different thermal expansion ratio than that of the membrane. Illustrative materials to be used to provide the substrate include fused silica, quartz, Zerodur® (a lithium aluminum silicon oxide glass-ceramic), polycrystal glass (soda lime glass), silicon, and sapphire. The substrate may comprise (or consist) of any of these materials or combinations thereof. Unlike the membrane layer, the thickness of the substrate (taken along the z axis) is not particularly limited. Similarly, the other two dimensions of the substrate (taken along the xy plane) are also not particularly limited. As described above, patterning may be used to alter the morphology of the substrate so as to define any of the suspended regions and supported regions described above.

As noted above, the heterostructure used in the present methods comprises a bonding layer between the overlying membrane layer and the underlying substrate. The bonding layer functions as a “glue” to adhere the membrane layer at one interface formed with a surface of the bonding layer and the membrane layer; and to adhere the substrate at an opposing interface formed with an opposing surface of the bonding layer and the substrate. The adhesion may include the bonding layer forming bonds, e.g., covalent bonds, to one or both of the membrane layer and the substrate in the bonded heterostructure. Such bonds may form during the heating step of the present methods. The bonding layer is capable of curing at the temperature being used during the heating step of the present methods. The chemical nature of the curing depends upon the composition of the bonding layer. Curing may involve transitioning to a more solid state (at the temperature being used during the heating step) from a more liquid state (at a lower temperature, e.g., room temperature). Curing may involve transitioning to a more condensed state (at the temperature being used during the heating step) from a more porous state (at a lower temperature, e.g., room temperature). Curing may involve chemical reactions, including the breaking of chemical bonds and/or the formation of chemical bonds (i.e., crosslinks) within the bonding layer. Moreover, generally, the bonding layer is capable of retaining its cured state during, and after, the cooling step of the present methods. Finally, generally, the bonding layer is capable of achieving a strain free state (of the membrane layer) at the temperature being used during the heating step of the present methods. By “strain free state,” it is meant that the strain in the membrane layer at the temperature being used during the heating step is substantially zero. This encompasses zero strain as well as small deviations from zero strain, e.g., ±0.005%, ±0.003%, ±0.001%.

The composition of the bonding layer may be selected to achieve any combination of the functions described above, including each such function. An illustrative material capable of each of these functions is hydrogen silsesquioxane. The curing of hydrogen silsesquioxane involves breaking Si—H bonds, forming Si—O crosslinks, and releasing H₂, leading to a transition from a more porous state to a more condensed state. In embodiments, the bonding layer comprises (or consists of) hydrogen silsesquioxane. Other materials similar to hydrogen silsesquioxane may be used, e.g., tetraethyl orthosilicate. Solvent(s) may be included in the bonding layer. Such solvent(s) are generally removed, e.g., via evaporation, during heating to provide the cured bonding layer.

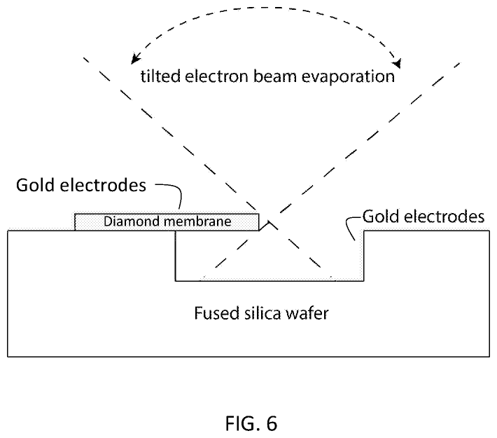

The heterostructure used in the present methods may further comprise one or more electrodes configured to apply an electric potential to the strained membrane layer. As further described below, such electrode(s) enable further tuning of the strain in the strained membrane layer via electrostatic control. This type of strain tuning may be referred to as active strain tuning and is distinguished from the strain generated in the membrane layer as otherwise described herein, which may be referred to as passive strain tuning. As illustrated in FIG. 6, the electrodes may be in the form of conductive layers (in this embodiment, gold layers) in contact with a portion of the strained membrane layer (in this embodiment, a strained diamond membrane layer) and a portion of the underlying substrate (in this embodiment, patterned fused silica). Fabrication of the electrode layers and the implementation of electrostatic control may be carried out using known techniques. (See Koch, Jens, et al. Physical Review A 76.4 (2007): 042319 and Barends, Rami, et al. Physical review letters 111.8 (2013): 080502, both of which are hereby incorporated by reference in their entirety.) The present methods may include the step of forming the electrode(s) and or applying the electric potential to the membrane layer via the electrode(s) to alter the strain profile of the strained membrane layer, i.e., to achieve active strain tuning.

Referring back to the steps of the present methods, as noted above, the heating step comprises heating the heterostructure. The conditions under which the heating is carried out include parameters such as heating temperature, heating time (which may refer to the period of time the heterostructure is at the selected heating temperature), heating atmosphere, etc. The conditions are selected to cure the bonding layer to form the bonded heterostructure. This may include formation of chemical crosslinks within the bonding layer; formation of bonds between the bonding layer and the overlying membrane layer, the underlying substrate, or both; evaporation of solvent(s); etc., and combinations thereof. The particular values of the parameters depend upon the composition of the bonding layer. Illustrative values for the heating temperature include at least 450° C., at least 475° C., at least 500° C., at least 550° C., at least 600° C., or in a range of from 450° C. to 650° C. Heating time may be in a range of from 1 hour to 15 hours. The atmosphere may be an inert atmosphere (e.g., Ar gas).

The method further comprises cooling the bonded heterostructure from the heating temperature to a lower temperature. The cooling converts the membrane layer in the bonded heterostructure to a strained membrane layer characterized by any of the strain profiles described herein. The temperature to which the bonded heterostructure is cooled (cooling temperature) may depend upon the desired application for the bonded heterostructure and may be room temperature (i.e., 20° C. to 25° C.) or a temperature lower than room temperature, e.g., 0° C. or less, 100 K or less, 10 K or less, or 5 K or less, e.g., 4 K. Other conditions, e.g., cooling time (which may refer to the period of time to bring the bonded heterostructure from its heating temperature to its cooling temperature), cooling atmosphere, etc. may be selected as desired.

As noted above, the present methods may involve use of a patterned membrane layer, a patterned bonding layer, a patterned substrate, or combinations thereof. Thus, the present methods may further comprise one or more patterning steps which may employ various lithography and etching techniques. Generally, the substrate is patterned prior to heating the heterostructure while the membrane layer is patterned after heating the heterostructure, but prior to cooling the heterostructure. For example, the substrate may be patterned; next, the bonding layer may be applied to the patterned substrate (as a result, the applied bonding layer may have a pattern corresponding to that of the patterned substrate); next, the membrane layer may be applied to the bonding layer to form the heterostructure; next, the heterostructure may be heated as described herein to form the bonded heterostructure; next, the membrane layer may be patterned; next, the bonded heterostructure may be cooled as described herein to convert the patterned membrane layer in the bonded heterostructure to a strained, patterned membrane layer. Additional details regarding patterning steps are provided in the Example, below.

It is noted that in the structures described in X. Guo, et al., Nano Letters 21, 10392 (2021), the diamond membrane layers are not patterned as that term has been defined herein. In addition, the substrates of the structures described in X. Guo, et al., Nano Letters 21, 10392 (2021) do not include embedded cavities.

Other additional steps that may be used in the present methods include, e.g., forming electrode(s), applying a voltage to the electrode(s). Regarding electrode formation, various thin film deposition techniques may be used.

As noted above, the present methods provide strained membrane layers characterized by any of the strain profiles described herein. Strain values exhibited by the strained membrane layers may be at least 0.1%, at least 0.15%, at least 0.20%, at least 0.25%, at least 0.30%, at least 0.35%, at least 0.40%, at least 0.45%, at least 0.50%, at least 0.55%, at least 0.60%, or in a range of from 0.1% to 1%. These strain values may refer to strain values at specific locations within the strained membrane layers or average strain values of specific regions within the strained membrane layers. With respect to strain values at specific locations within the strained membrane layer, a strained membrane layer may comprise one or more locations exhibiting zero strain (0±0.005%, 0±0.003%, or 0±0.001% as described above), provided the strained membrane layer comprises one or more additional locations exhibiting non-zero strain values. However, generally, all locations within the strained membrane layer exhibit non-zero strain values. The strain values disclosed herein may refer to calculated or experimentally determined values. The strain values disclosed herein may refer to a maximum strain value exhibited by the strained membrane layer or a region(s) or a location(s) thereof. The strain values disclosed herein may be reported with respect to a particular temperature, including any of the cooling temperatures described above. The strain values disclosed herein refer to absolute values; the strain type at specific location(s) or region(s) may be either compressive or tensile as described above. The strain values disclosed herein refer to those achieved by passive strain tuning. Active strain tuning may be additionally applied as described above to adjust, including to further increase the strain values.

The present disclosure encompasses the bonded heterostructures formed using the present methods, i.e., those comprising the strained membrane layers characterized by any of the strain profiles described herein. In embodiments, the bonded heterostructure comprises (or consists of) a cured bonding layer comprising (or consisting of) hydrogen silsesquioxane or tetraethyl orthosilicate; a strained diamond membrane layer having one or more color centers therein; and a substrate of fused silica, sapphire, or a lithium aluminum silicon oxide glass-ceramic. Devices incorporating the bonded heterostructures are also encompassed. Such devices include those used in quantum sensing and quantum communication applications.

### EXAMPLE

The bonded heterostructure 200 shown in FIG. 2A was fabricated as follows. First, a fused silica substrate was patterned using photolithography (with AZ 4620 as photoresist) and fluorine-based inductively coupled plasma (ICP) etching to form the rectangularly shaped cavity 220. Next, hydrogen silsesquioxane in a solvent was spin-coated onto the upper surface of the patterned substrate. Next, a diamond membrane was transferred onto the coated, patterned substrate in the position shown in FIG. 2A. (The unpatterned diamond membrane itself was formed as described in X. Guo, et al., Nano Letters 21, 10392 (2021).) Next, the heterostructure was heated to a temperature of about 600° C. for a period of time to cure the hydrogen silsesquioxane and form a bonded heterostructure. Next, prior to cooling, the diamond membrane was patterned using e-beam lithography (with PMMA as e-beam resist, aluminum oxide as hard mask) and chlorine-based ICP etching to define the three suspended regions 222a-c. Finally, the bonded heterostructure was cooled to a cryogenic temperature (e.g., 4 K) to induce high strain and convert the patterned diamond membrane to a patterned, strained diamond membrane. Photoluminescence spectra of color centers (e.g., GeV⁻) within the patterned, strained diamond membrane were obtained. As shown in FIG. 7, the splitting between C-peak and D-peak of the spectra reflects the magnitude of the strain.

Similar steps were used to fabricate the bonded heterostructure 400 shown in FIG. 4A. In addition, other similar bonded heterostructures were fabricated using similar steps but with other substrates, including Zerodur® and sapphire.

In all cases, the integrity of the bonded heterostructures was retained despite high strain induced in the membrane layers, i.e., the strained membrane layers were not damaged and did not debond from the underlying bonding layer.

COMSOL Multiphysics simulations were carried out to measure strain profiles for bonded heterostructures, including the bonded heterostructures of FIGS. 2A, 4A, and 5A. Briefly, the simulations were carried out as follows. First, a model was defined by plotting the geometry of the substrate, the bonding layer, and the membrane layer. Next, material properties of the substrate, the bonding layer, and the membrane layer were defined, e.g., the thermal expansion ratio, thermal conductivity, Young's modulus, etc. Next, the physical process and the initial conditions were defined, including the heating temperature, the cooling temperature, and that the heterostructure is strain-free at the heating temperature. Finally, the simulations were run and the strain profile at the cooling temperature was extracted. Strain profiles extracted for the bonded heterostructures of FIGS. 2A, 4A, and 5A are shown in FIGS. 3A-3B, 4B-4C, and 5B-5C, respectively, and have been further described above.

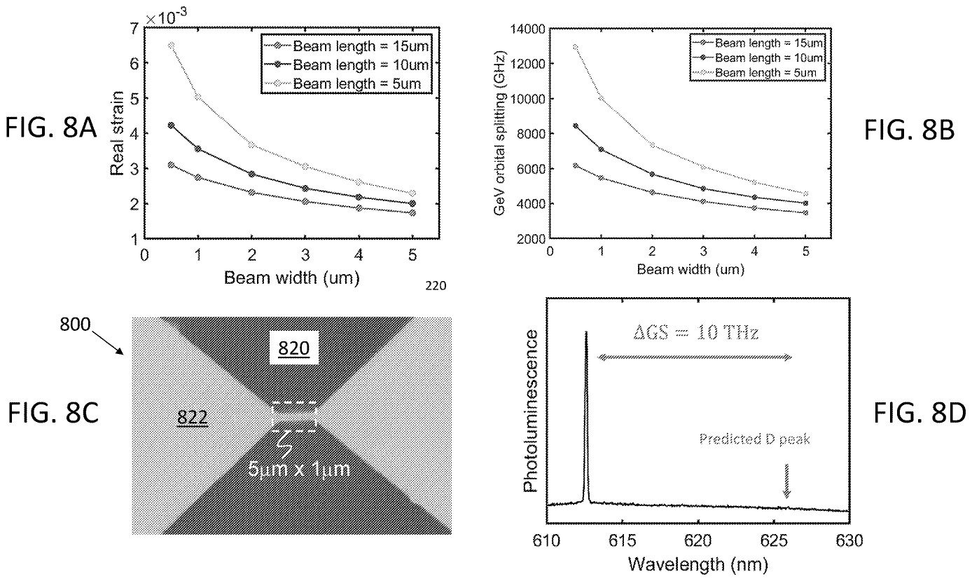

Other bonded heterostructures were fabricated as described above with respect to FIGS. 2A and 2B. A portion of a bonded heterostructure 800 is shown in FIG. 8C. A suspended region 822 of the bonded heterostructure 800 is in the form of a bow-tie shaped beam (similar to 222b and 222c of the bonded heterostructure 200 of FIG. 2A). A cavity 820 defined in the substrate is also labeled. However, the dimensions of the beam in FIG. 8C have been tuned to induce a larger strain in the diamond membrane and, thus, further improve coherence of color centers (here GeV⁻) within the strained diamond membrane. Specifically, by decreasing the length and width of the narrow, rectangular central portion of the beam, the strain will be concentrated within a smaller area, generating a larger strain magnitude. The increase in strain and thus, increase in orbital splitting, as length and width are decreased is demonstrated using COMSOL simulations and calculations as shown in FIGS. 8A and 8B, respectively. The dimensions of the central portion of the beam shown in FIG. 8C are labeled. FIG. 8D shows a photoluminescence spectrum from a GeV⁻ color center within the central portion of the beam. The orbital splitting is gigantic such that the D-transition is fully suppressed. However, the position of D-peak may be predicted using the calculated value of orbital splitting in FIG. 8B.

The word “illustrative” is used herein to mean serving as an example, instance, or illustration. Any aspect or design described herein as “illustrative” is not necessarily to be construed as preferred or advantageous over other aspects or designs. Further, for the purposes of this disclosure and unless otherwise specified, “a” or “an” means “one or more.”

The foregoing description of illustrative embodiments of the disclosure has been presented for purposes of illustration and of description. It is not intended to be exhaustive or to limit the disclosure to the precise form disclosed, and modifications and variations are possible in light of the above teachings or may be acquired from practice of the disclosure. The embodiments were chosen and described in order to explain the principles of the disclosure and as practical applications of the disclosure to enable one skilled in the art to utilize the disclosure in various embodiments and with various modifications as suited to the particular use contemplated. It is intended that the scope of the disclosure be defined by the claims appended hereto and their equivalents.

Any directional language used in the present disclosure such as top, bottom, upper, lower, above, below, over, under, and the like is not necessarily intended to be limiting, but rather to provide a point of reference to other elements being described.

If not already included, all numeric values of parameters in the present disclosure are proceeded by the term “about” which means approximately. This encompasses those variations inherent to the measurement of the relevant parameter as understood by those of ordinary skill in the art. This also encompasses the exact value of the disclosed numeric value and values that round to the disclosed numeric value.

What is claimed is:

1. A method of forming a strained membrane layer, the method comprising:
(a) heating a heterostructure, the heterostructure comprising a membrane layer, a substrate, and a bonding layer between the membrane layer and the substrate, under conditions to cure the bonding layer and form a bonded heterostructure, wherein the membrane layer and the substrate have a thermal expansion ratio mismatch; and
(b) cooling the bonded heterostructure under conditions to convert the membrane layer in the bonded heterostructure to a strained membrane layer characterized by a strain profile comprising a non-zero strain value, wherein the strained membrane layer comprises a suspended region and a supported region and wherein the suspended region exhibits a strain value greater than a strain value exhibited by the supported region.

2. The method of claim 1, wherein the suspended region exhibits an average strain value greater than an average strain value exhibited by the supported region.

3. The method of claim 1, wherein a maximum strain value in the strained membrane layer is located in the suspended region.

4. The method of claim 1, wherein the suspended region exhibits a strain value of greater than 0.1%.

5. The method of claim 4, wherein the suspended region exhibits a strain value of greater than 0.25%.

6. The method of claim 1, wherein the suspended region is one of a plurality of suspended regions of the strained membrane layer.

7. The method of claim 6, wherein all suspended regions exhibit a strain value greater than a strain value exhibited by the supported region.

8. The method of claim 1, wherein the substrate is patterned.

9. The method of claim 8, wherein an embedded cavity is defined in the substrate.

10. The method of claim 8, wherein the strained membrane layer is positioned relative to a cavity defined in the substrate such that a crystallographic axis of the strained membrane layer is parallel to a length of the cavity.

11. The method of claim 1, wherein the strained membrane layer is patterned.

12. The method of claim 11, wherein the suspended region is in the form a beam having two opposing exposed sides and two opposing anchored sides.

13. The method of claim 1, wherein the substrate is patterned and the strained membrane layer is patterned.

14. The method of claim 1, wherein the bonding layer comprises hydrogen silsesquioxane or tetraethyl orthosilicate; the membrane layer is a diamond membrane layer comprising a color center; and the substrate is fused silica, sapphire, or a lithium aluminum silicon oxide glass-ceramic.

15. The method of claim 1, wherein the membrane layer has a thermal expansion ratio that is greater than that of the substrate.

16. The method of claim 15, wherein the membrane layer is a diamond membrane layer.

17. The method of any claim 1, further comprising patterning the membrane layer after step (a) and prior to step (b).

18. The method of claim 18, further comprising patterning the substrate prior to step (a).

19. The method of claim 1, wherein the membrane layer has an average thickness of less than 1 μm.

20. A bonded heterostructure comprising a strained membrane layer characterized by a strain profile comprising a non-zero strain value; a substrate; and a cured bonding layer between the strained membrane layer and the substrate, wherein the strained membrane layer is composed of a material having a thermal expansion ratio mismatch with the substrate, and the strained membrane layer comprises a suspended region and a supported region, wherein the suspended region exhibits a strain value greater than a strain value exhibited by the supported region.
